(19) United States
(12) Patent Application Publication
(10) Pub. No.: US 2023/0180399 A1
(43) Pub. Date: Jun. 8, 2023

(54) DESIGN TO PROTECT CHIP-ON-FLEX FOR DUAL BENDING

(71) Applicant: Meta Platforms Technologies, LLC, Menlo Park, CA (US)

(72) Inventor: Kyung Won Park, Bellevue, WA (US)

(21) Appl. No.: 17/544,332

(22) Filed: Dec. 7, 2021

(51) Int. Cl. H05K 5/00; G06F 1/16; G02B 27/01

(52) U.S. Cl. CPC H05K 5/0017; G06F 1/163; G02B 27/0176; G02B 2027/0178

(57) ABSTRACT

A display module includes a display panel having a display active area including a plurality of display elements and a bezel region located outside of the display active area, a support plate underlying the display panel, a display driver integrated circuit (DDIC) disposed over a surface of the support plate opposite to the display panel, a flexible conductor attached to the display panel within the bezel region and electrically connecting the plurality of display elements with the display driver integrated circuit, and a support element directly underlying the flexible conductor adjacent to the bezel region.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a cross-sectional illustration of a display module having an unsupported chip-on-flex interconnect according to some embodiments.

FIG. 2 is a cross-sectional illustration of a display module having a supported chip-on-flex interconnect according to some embodiments.

FIG. 3 is a magnified view of the supported chip-on-flex interconnect of FIG. 2 according to some embodiments.

FIG. 4 is a photographic image showing a perspective view of a display module having a supported chip-on-flex interconnect according to certain embodiments.

FIG. 5 is a cross-sectional illustration of a display module having a supported chip-on-flex interconnect according to further embodiments.

FIG. 6 is a perspective illustration showing the display module of FIG. 5 according to some embodiments.

FIG. 7 is an illustration of exemplary augmented-reality glasses that may be used in connection with embodiments of this disclosure.

FIG. 8 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Optical displays are ubiquitous in emerging technologies, including wearable devices, smart phones, tablets, laptops, desktop computers, and other display systems. An optical display may include a display module that is configured to generate and project an image to a user. The manufacture of high performance and high density optical displays, however, may rely on packaging solutions that include a high density of interconnects that are prone to failure during manufacture and/or handling.

In a chip-on-flex (COF) or other direct chip attachment (DCA) assembly, for example, a microchip or die may be directly mounted and electrically connected to a flexible circuit in lieu of a relatively rigid printed circuit board. A flexible circuit (or flexible conductor), i.e., a circuit built on a flexible substrate, may be used to route electrical connections from a front side of a device to its backside thus simplifying design and manufacture. However, particularly for high density architectures, dynamic bending of the flexible substrate may damage conductive traces therein and/or compromise electrical connections, i.e., along an interface between the flexible substrate and an adjacent component of the display module. Thus, notwithstanding recent developments, it would be advantageous to provide methods and structures to enable high density, high performance, and mechanically robust optical displays.

In accordance with various embodiments, a display module may include a display panel having an array of individual display elements defining an active area. One or more display elements can be grouped to form pixels. Each of the display elements may include a light emitting diode (LED), for example, and suitable control circuitry configured to generate and distribute control signals to selectively illuminate the pixels to project an image.

In particular embodiments, the display panel may include a semiconducting material such as silicon, e.g., single crystal silicon. Individual die used to form the display panel may be cut from a silicon wafer. The higher carrier mobility of a single crystal silicon display panel (i.e., relative to glass, polymer, or even polycrystalline semiconductors) and the attendant improvement in device operating speed may enable the creation of an increasingly complex data selection interface between the display elements and the display driver circuitry. A higher density data selection interface may enable higher pixel densities within the display active area and higher quality images.

Located over the display panel, according to some embodiments, a transparent encapsulation layer may be disposed over an upper emissive surface of the display panel's active area. The encapsulation layer may include a layer of cover glass and one or more optical layers, e.g., filters such as a color filter and a polarizing film. The cover glass may include an alkali-free glass composition, for example. An example polarizing film may include a Pancharatnam Berry Phase (PBP) optical layer. The cover glass may be secured to the display panel by a peripheral layer of a suitable adhesive such that the adhesive may be located outside of the active area of the display panel.

Mechanical support for the display module may be provided by a support plate that underlies and may be bonded to the display panel. The support plate may be substantially rigid, may include a thermally conductive material, and thus may be additionally configured as a heat sink to provide passive or active cooling for the display module. By way of example, a support plate may have a thermal conductivity of at least approximately 100 W/mK and may include a layer of aluminum metal or alloys thereof. A layer of a thermally conductive adhesive (e.g., thermally conductive tape) may be used to bond the display panel to the support plate. The support plate may serve as an electric ground for the display module.

As will be appreciated, integration of the display elements with the control circuitry can affect pixel-level interconnects, including the size and density of a pixel array, and ultimately the quality, performance, and cost of the display module. The control circuitry may include a display driver integrated circuit (DDIC), which may be configured to apply current to selected diodes, determining which pixels get turned on and which pixels remain off. In some embodiments, the brightness of each pixel may be proportional to the amount of applied current.

Display driver integrated circuits (DDICs), which may also be referred to herein as driver ICs, may receive image data and deliver analog voltages or currents to activate one or more pixels within the display. Driver ICs may include gate drivers and source drivers and may include an array of driving transistors, which may be formed using conventional CMOS processing. In accordance with various embodiments, a gate driver may refer to a power amplifier that accepts a low-power input from a controller IC and produces a high-current drive input for the gate of a transistor, such as an insulated gate bipolar transistor (IGBT) or power metal-oxide-semiconductor field effect transistor (MOSFET). In some embodiments, a gate driver may be configured to turn on and off selected transistors within each pixel cell across a horizontal row of the display area. When the transistors are turned on, a source driver may generate voltages that are applied to each pixel cell on that row for data input. In some embodiments, a source driver may be integrated with a digital-to-analog converter (DAC) for generating analog output voltages from digital input data to drive individual pixels.

The DDIC may be located over a backside of the support plate opposite to the display panel. In some embodiments, the DDIC may overlie a support layer that may itself be bonded to the support plate. The support layer may protect the DDIC from impact, bending, twisting, etc. during manufacture of the display module (i.e., prior to securing the DDIC to the support plate).

A chip-on-flex (COF) packaging technology may be used to integrate the display elements with the DDIC, optionally via a data selector (i.e., multiplexer) array. As used herein, the terms “multiplexer” or “data selector” may, in some examples, refer to a device adapted to combine or select from among plural analog or digital input signals, which are transmitted to a single output. Multiplexers may be used to increase the amount of data that can be communicated within a certain amount of space, time, and bandwidth.

In some embodiments, the display driver integrated circuit may be attached and electrically connected to a flexible conductor and direct bonding methods may be used to electrically connect the flexible conductor to the active display panel. In accordance with certain embodiments, the DDIC may be bonded to the flexible conductor, e.g., using a layer of thermally and electrically conductive tape, and also electrically grounded to the support plate via the support layer. Respective layers of an electrically conductive pressure sensitive adhesive (PSA) may be disposed between the flexible conductor and the support layer and between the support layer and the support plate. The thermally conductive tape may include graphite tape, for example. In some embodiments, ultrasonic or thermosonic wire bonding techniques may be used to electrically connect the DDIC chip to the flexible conductor.

The flexible conductor may be routed from a backside of the display module to a front side of the display module where it is electrically connected to the display panel. The flexible conductor may include a main body that is formed from a pliable dielectric material such as polyimide or polytetrafluoroethylene (PTFE), although further flex materials are contemplated. The flexible conductor may additionally include a plurality of conductive traces (e.g., copper lines and plugs) for conducting electricity along or through the main body. The flexible conductor may include a copper-clad laminate material, for example. In some embodiments, the flexible conductor main body may have a thickness of approximately 50 to approximately 100 micrometers, e.g., 50, 60, 70, 80, 90, or 100 micrometers, including ranges between any of the foregoing values, and the conductive traces may have a thickness of approximately 20 to approximately 40 micrometers, e.g., 20, 30, or 40 micrometers, including ranges between any of the foregoing values.

In an assembled display module, the flexible conductor may be characterized by a dual bending architecture and may include two or more bends, i.e., a first bending region and a second bending region. In some embodiments, the flexible conductor may be bent into an “S” shape. In particular examples, the first bending region may be located adjacent to the display panel and the support plate, and the second bending region may be located adjacent to the transparent encapsulation layer. The first bending region may include a bend in the flexible conductor of approximately −180° whereby regions of a given surface of the flexible conductor may be respectively disposed over a back surface of the support plate and over a front surface of the display panel. With such a configuration, a portion of the flexible conductor may be disposed between the support plate and the DDIC.

The radius of curvature of the flexible conductor within the bending regions may be approximately an order of magnitude greater than a thickness of the flexible conductor. By way of example, the first bending region may have a radius of curvature (r1) of approximately 2 mm, e.g., 1.8, 1.9, 2.0, 2.1, or 2.2 mm, including regions between any of the foregoing values. The second bending region may have a radius of curvature (r2) of approximately 0.8 mm, e.g., 0.7, 0.8, or 0.9 mm, including regions between any of the foregoing values. As will be appreciated, lesser or greater radii of curvature may be used.

An inactive area of the display panel located adjacent to and outside of the active area may be referred to as a bezel region. The bezel region may be characterized by a width w, whereby a portion of the flexible conductor may overlie the front face of the display panel, i.e., within the bezel region. In particular embodiments, the width (w) of the bezel region may range from approximately 1 mm to approximately 1.5 mm, e.g., 1.0, 1.1, 1.2, 1.3, 1.4, or 1.5 mm, including ranges between any of the foregoing values.

Electrical connections between the flexible conductor and the front surface of the display panel may be formed within the bezel region, i.e., between the first and second bending regions of the flexible conductor. An electrically conductive adhesive bond between the flexible conductor and a front side of the display panel may be formed using anisotropic conductive film (ACF) bonding, for example. In some embodiments, the display module may include a strain relief layer that is configured to provide support to the flexible conductor proximate to the display panel. The strain relief layer may underlie the flexible conductor immediately adjacent to the display panel and may stabilize the ACF bonding region, e.g., during an ACF bonding process.

An anchoring element may be disposed over and bonded to the flexible conductor opposite to the ACF bonding region and the strain relief layer. A surface of the flexible conductor may be bonded to a lower surface of the anchoring element. In some embodiments, the flexible conductor may include a second bending region whereby the flexible conductor may be re-bent (e.g.,)+180° and bonded to an upper surface of the anchoring element. The extension of the flexible conductor over the anchoring element may provide additional surface area to reroute a high density of conductive traces within the flexible conductor to the ACF bonding area. A pressure sensitive adhesive (PSA) (e.g., double-sided tape) may be used to bond the flexible conductor to the lower and upper surfaces of the anchoring element on either side of the second bending region. In certain examples, the anchoring element may include a relatively stiff material, such as polycarbonate.

As disclosed further herein, the integrity of both the ACF bonding interface and the conductive traces within the flexible conductor may be protected by introducing a support element that underlies the flexible conductor within an area between the first and second bending regions. In some embodiments, the support element may additionally underlie the flexible conductor within the first bending region. A support element may provide a support surface upon which a portion of the flexible conductor may overlie. A support element may inhibit deformation of the flexible conductor and thus decrease or eliminate strains sufficient to cause failure of conductive traces therein and/or along the ACF bond interface between the flexible conductor and the display panel. As used here, the “failure” of an electrical connection may include an undesirable interruption or loss of electrical continuity.

In particular embodiments, the support element may be integral with, and extend from, the support plate. That is, the support element and the support plate may constitute a unitary part. The support element may abut and provide mechanical support to the flexible conductor within the first bending region and/or between the first bending region and the second bending region. In some embodiments, the flexible conductor may conformally overlie and directly contact the support element. In some embodiments, a flexible conductor may overlie the support element and define a gap therebetween. The flexible conductor and the support element may be unbonded and accordingly displaceably disposed with respect to each other.

Disclosed herein are display structures that include a display active area located over a front face of a display panel and a display driver integrated circuit (DDIC) located over a back face of the display panel opposite to the front face where electrical connections between the display active area and the display driver integrated circuit are made through a flexible circuit. The backside placement of the DDIC enables a greater percentage of the silicon's front face to be dedicated to the active display panel, which may correlate to a significant improvement in material utilization and substantial cost savings. The instant approach preserves front-side area of the silicon chip for the device active area and thus may enable a larger active area for a given chip size.

The flexible circuit may include a dual bending architecture, which may be configured to accommodate both a large number of electrical connections between the flexible circuit and the display panel and electrical connections between the flexible circuit and the DDIC. In a region adjacent to the display panel, the flexible circuit may overlie a support element that prevents or inhibits excessive strains in the flexible circuit as well as across a bonding interface between the flexible circuit and the display panel.

According to some embodiments, an LED-based (e.g., OLED-based or micro-OLED-based) device may include a display module having a display active area disposed over a front face of a silicon display panel, a DDIC mounted over a back face of the silicon display panel, and a support plate located between the back face of the silicon display panel and the DDIC. The DDIC may be electrically connected to the front face of the silicon display panel by conductive traces located within a flexible conductor that traverses between the front and back sides of the display module. In a region adjacent to the silicon display panel, the flexible conductor may be disposed over a support element that extends from and is integral with the support plate. The support element may be configured to inhibit or prevent flexure of a portion of the flexible conductor overlying the silicon display panel.

As will be appreciated, the display modules described herein may include LEDs or microLEDs. Moreover, the LED-based displays may include organic LEDs (OLEDS), including micro-OLEDs. The LED-based displays may be incorporated into a variety of devices, such as wearable near-eye displays (NEDs). The disclosed methods and structures may be used to manufacture low cost, high resolution displays having a commercially-relevant form factor (e.g., having one or more lateral dimensions greater than approximately 1.6 inches). In some embodiments, the display active area may have at least one areal dimension (i.e., length or width) greater than approximately 1.3 inches, e.g., approximately 1.4, 1.5, 1.6, 1.7, 1.8, 1.9, 2.0, 2.25, 2.5, 2.75, or 3 inches, including ranges between any of the foregoing values, although larger area displays are contemplated. In certain examples, the display resolution may be greater than approximately 4K (i.e., 2160p).

Features from any of the embodiments described herein may be used in combination with one another in accordance with the general principles described herein. These and other embodiments, features, and advantages will be more fully understood upon reading the following detailed description in conjunction with the accompanying drawings and claims.

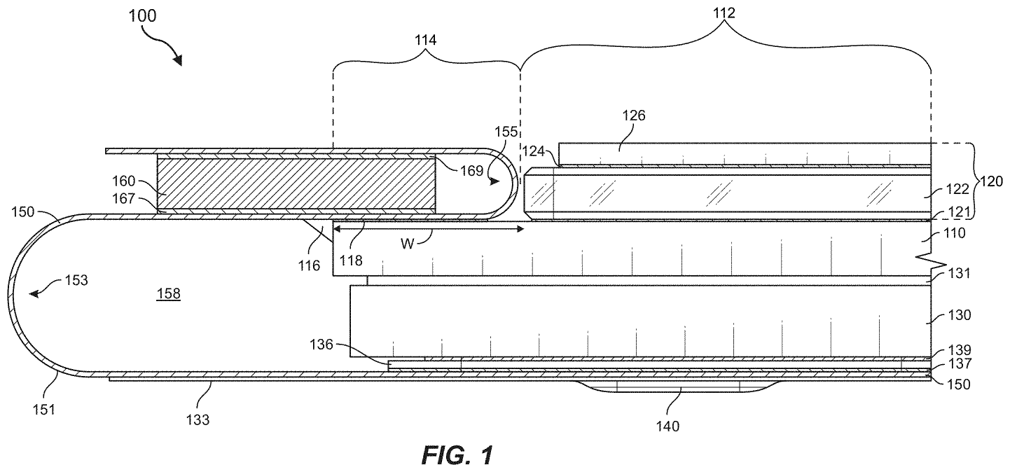

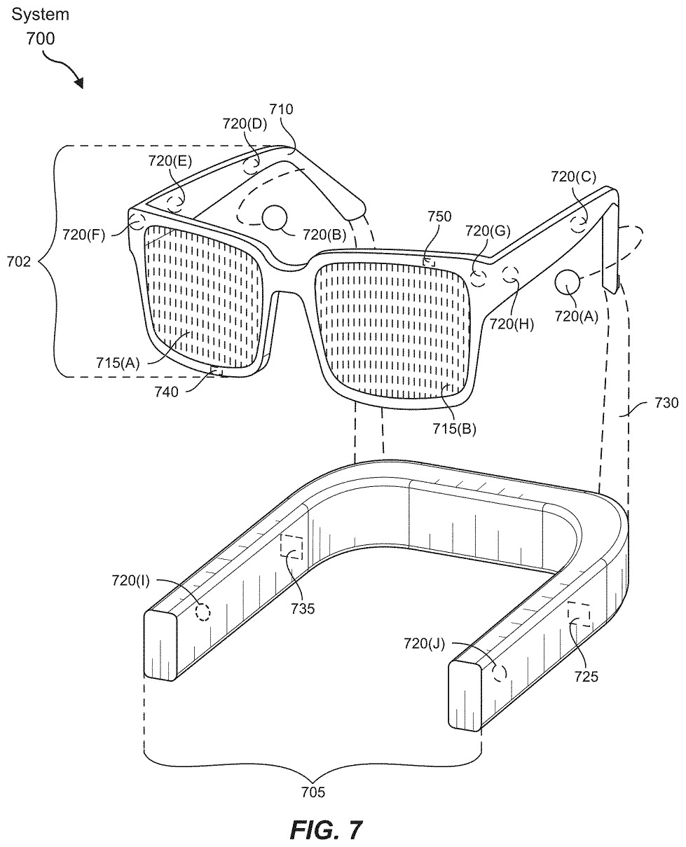

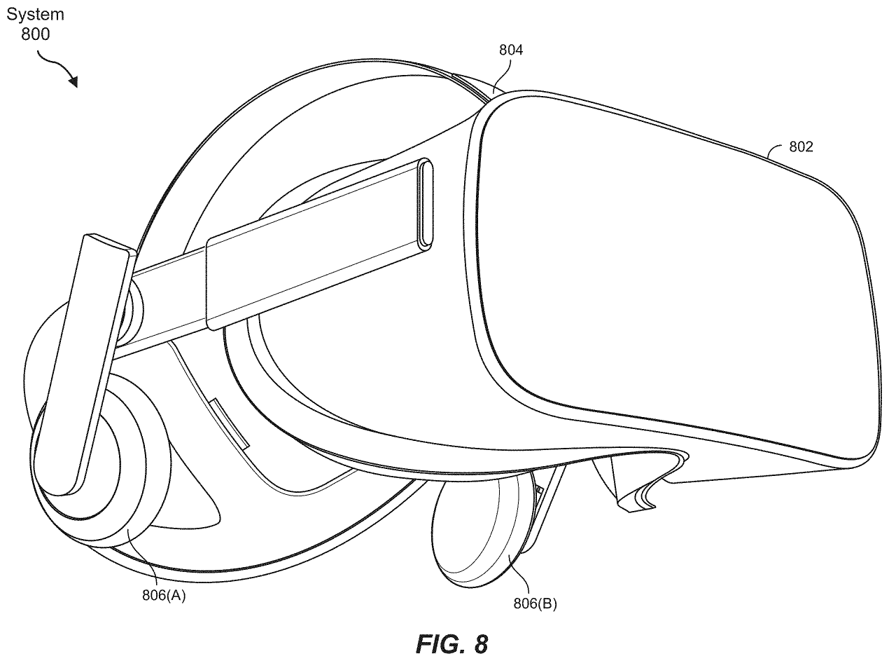

The following will provide, with reference to FIGS. 1-6, detailed descriptions of display modules including a mechanically robust chip-on-flex architecture. The discussion associated with FIGS. 7 and 8 relates to various virtual reality platforms that may include a display module as described herein.

A cross-sectional view of an example and comparative display module is shown in FIG. 1. Display module 100 includes a display panel 110 having an active area 112 and an inactive area (bezel region) 114 adjacent to the active area 112. The bezel region 114 may have a width (w). Disposed over the display panel 110 within the display panel's active area 112, a transparent encapsulation layer 120 may include, from bottom to top, a layer of cover glass 122, an optical layer 124, and a polarizing film 126. An adhesive layer 121 may be used to bond the display panel 110 to the cover glass 122.

The display panel 110 may be disposed over and bonded to a support plate 130, e.g., using a thermally and electrically conductive adhesive layer 131. The thermally and electrically conductive adhesive layer 131 may include thermally conductive tape, for example. Support plate 130 may be configured as a heat sink and accordingly may be configured to withdraw heat from the display panel 110.

A DDIC 140 may be located over a backside of the support plate 130 opposite to the display panel 110. In some embodiments, the DDIC 140 may overlie a support layer 136 that may be bonded to the support plate 130. The support layer 136 may be a rigid or semi-rigid layer, for example, such as polycarbonate.

The display driver integrated circuit 140 may be attached and electrically connected to a flexible conductor 150 and direct bonding methods may be used to electrically connect the flexible conductor 150 to a top surface of the active display panel 110 within bezel region 114. The DDIC 140 may be bonded to the flexible conductor 150 using a layer of thermally and electrically conductive tape 133. In some embodiments, the DDIC 140 may be electrically grounded to the support plate 130 via support layer 136. Adhesive layers 137, 139 of an electrically conductive pressure sensitive adhesive (PSA) may be disposed between the flexible conductor 150 and the support layer 136 and between the support layer 136 and the support plate 130, respectively.

The flexible conductor 150 may include a main body 151 that is formed from a pliable dielectric material. The flexible conductor 150 may be routed from a backside of the display module 100 to a front side of the display module where it is electrically connected to the display panel 110. The flexible conductor 150 may include a dual bending architecture that includes two or more bends, i.e., a first bending region 153 and a second bending region 155. In some embodiments, the flexible conductor 150 may be bent into an “S” shape.

Referring still to FIG. 1, the first bending region 153 may be located adjacent to the display panel 110 and the support plate 130, and the second bending region 155 may be located adjacent to the transparent encapsulation layer 120. Regions of one surface of the flexible conductor 150 may be respectively disposed over a front surface of the display panel 110 and over a back surface of the support plate 130.

Electrical connections between the flexible conductor 150 and the front surface of the display panel 110 may be formed within the bezel region 114, i.e., between the first and second bending regions of the flexible conductor. An electrically conductive adhesive bond 118 between the flexible conductor and a front side of the display panel 110 may be formed using anisotropic conductive film (ACF) bonding, for example. In some embodiments, the display module 100 may include a strain relief layer 116 that is configured to provide support to the flexible conductor 150 proximate to the display panel 110. The strain relief layer 116 may underlie the flexible conductor 150 immediately adjacent to the display panel 110 and may stabilize the ACF bonding region 118, e.g., during an ACF bonding process. Adjacent to the strain relief layer 116, opposite to the display panel 110, the flexible conductor 150 may overlie an air gap 158 where the flexible conductor may be unsupported.

An anchoring element 160 may be disposed over and bonded to the flexible conductor 150 opposite to the strain relief layer 116 and the ACF bonding region 118. A surface of the flexible conductor 150 may be bonded to a lower surface of the anchoring element 160. In some embodiments, the flexible conductor may include a second bending region 155 wherein the flexible conductor 150 may be re-bent (e.g.,)+180° and bonded to an upper surface of the anchoring element 160. That is, a surface of the flexible conductor 150 may be bonded to both a lower surface of the anchoring element 160 and an upper surface of the anchoring element 160 on one side of the second bending region 155.

The extension of the flexible conductor 150 over the anchoring element 160 may provide additional surface area to reroute a high density of conductive traces within the flexible conductor 150 to the ACF bonding region 118. Respective layers 167, 169 of a pressure sensitive adhesive (PSA) (e.g., double-sided tape) may be used to bond the flexible conductor 150 to the lower and upper surfaces of the anchoring element 160. In certain examples, the anchoring element 160 may include a relatively stiff dielectric material, such as polycarbonate.

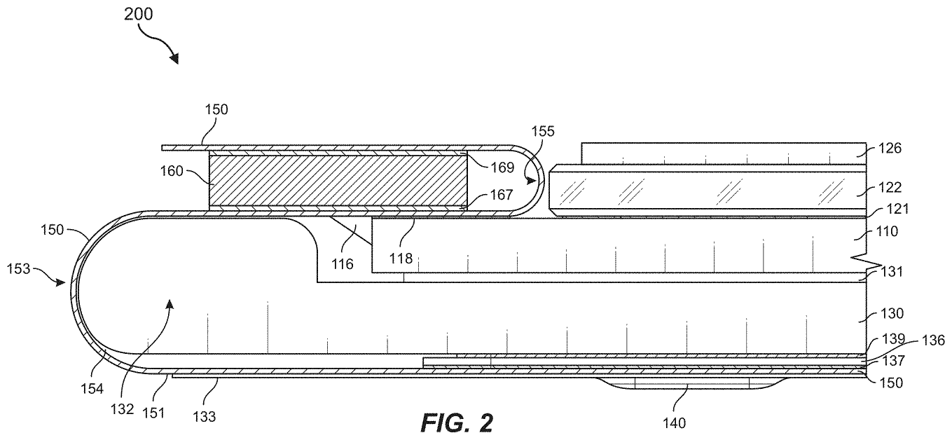

Referring to FIG. 2, in an example display module 200, the mechanical stability of both the ACF bonding region 118 and the conductive traces within the flexible conductor 150 may be protected by introducing a support element 132 immediately adjacent to the flexible conductor 150 within an area between the first bending region 153 and the second bending region 155. Support element 132 may fill or substantially fill airgap 158 shown in FIG. 1. In some embodiments, the support element 132 may abut the flexible conductor 150 within the first bending region 153. A support element 132 may provide a support surface upon which a portion of the flexible conductor 150 may overlie, i.e., directly overlie. A support element 132 may inhibit deformation of the flexible conductor 150 and thus decrease or eliminate strains sufficient to cause failure of conductive traces therein and/or along the ACF bond interface 118 between the flexible conductor 150 and the display panel 110.

In particular embodiments, the support element 132 may be integral with, and extend from, the support plate 130. In alternate embodiments, the support element 132 and the support plate 130 may be separate elements. As shown in FIG. 2, in some embodiments a top surface of the support element 132 may be co-planar or substantially co-planar with a top surface of the display panel 110.

The support element 132 may provide mechanical support to the flexible conductor 150 within the first bending region 153 and/or between the first bending region 153 and the second bending region 155. In some embodiments, the support element 132 may inhibit flexure of the flexible conductor 150 within or adjacent to the ACF bonding region 118. In some embodiments, the flexible conductor 150 may conformally overlie and directly contact the support element 132. In some embodiments, the flexible conductor 150 may overlie the support element 132 with one or more gaps 154 located therebetween. The flexible conductor 150 and the support element 132 may be unbonded and accordingly displaceably arranged with respect to each other.

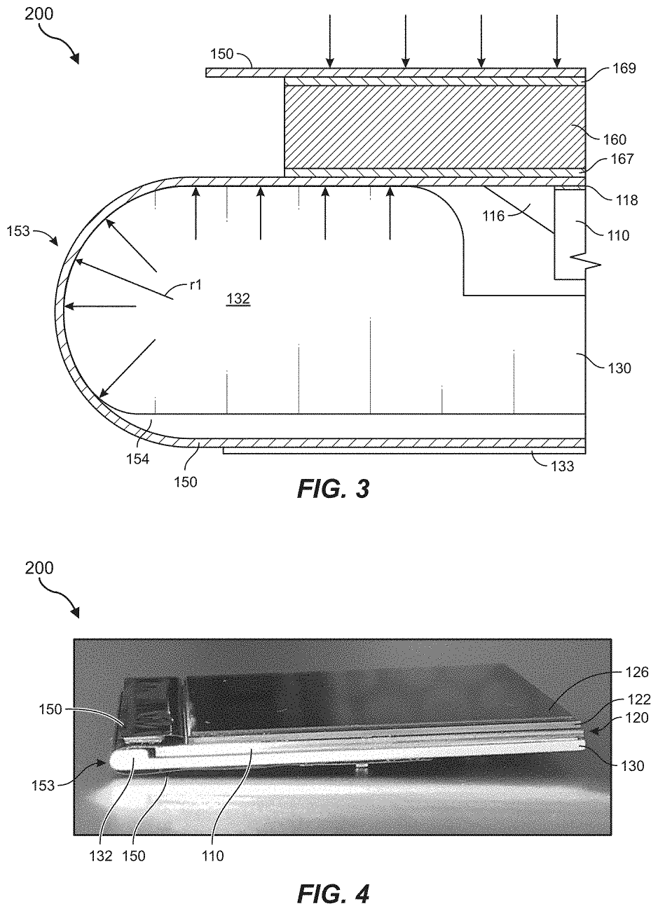

A magnified view of the display module 200 of FIG. 2, including support element 132, is shown in FIG. 3. Within first bending region 153, flexible conductor 150 may be characterized by a first radius of curvature (r1). Arrays of arrows schematically illustrate a balance of forces and a resulting zero or substantially zero net displacement of the flexible conductor. A perspective optical micrograph of display module 200 is shown in FIG. 4.

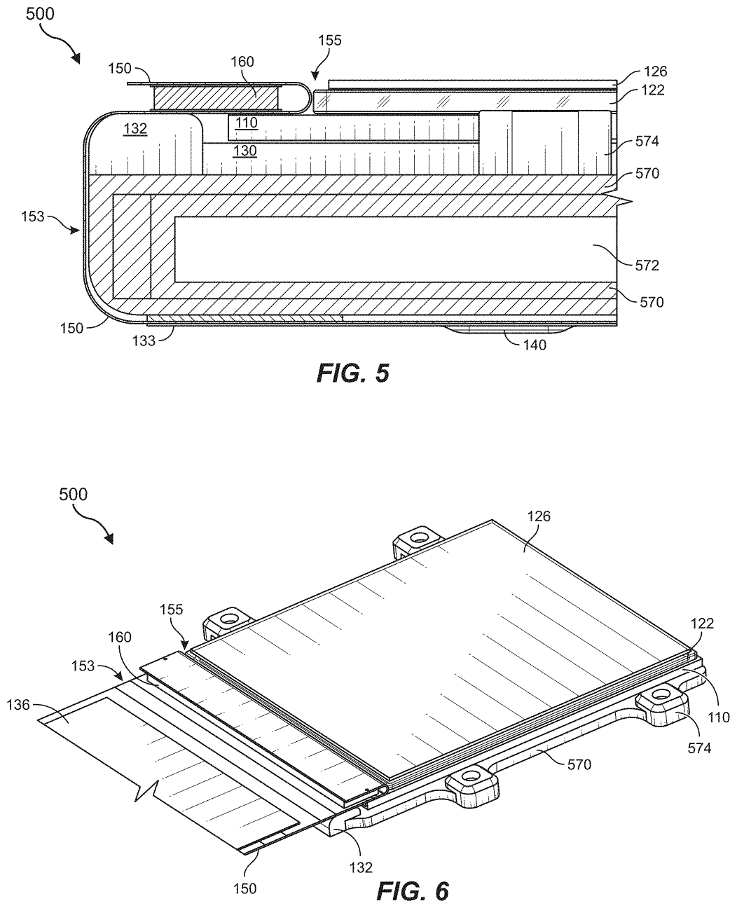

A further example display module is shown schematically in FIGS. 5 and 6. Display module 500 has a supported architecture and may include a support element 132 that is integral with and extends from support plate 130. Support element 132 provides a support surface for flexible conductor 150. Between the first bending region 153 and the second bending region 155, respective regions of flexible conductor 150 may overlie display panel 110 and support element 132. In some embodiments, neighboring regions of the flexible conductor 150 may be disposed between the anchoring element 160 and the display panel 110 and between the anchoring element 160 and the support element 132. Additionally, flexible conductor 150 may overlie support element 132 within the first bending region 153.

Support plate 130 and support element 132 may overlie a module housing 570. In some embodiments, module housing 570 may be formed from a thermally conductive material and may be configured to operate as a heat sink. In some embodiments, module housing 570 may include one or more fluid channels 572 through which a thermally-conductive fluid may flow. Module housing may additionally include one or more attachment elements 574, which may be configured to secure display module 500 to a further component, such as a display system (not shown).

As disclosed herein, a display module for providing visual content to a user includes a display panel driven by a display driver integrated circuit (DDIC). The display panel may be mounted over one side of a support plate whereas the DDIC may be mounted over the support plate opposite to the display panel. A flexible conductor may be electrically connected to each of the display panel and the DDIC to provide electrical communication therebetween.

The display panel may include silicon, although alternate materials such as glass or polyimide are contemplated. Metal (e.g., copper) traces may be incorporated into the flexible conductor to route electrical signals between the display panel and the control circuitry. Anisotropic conductive film (ACF) bonding may be used to form a high density array of electrical connections between the flexible conductor and the display panel. Dynamic bending of the flexible conductor during manufacture of the display module or thereafter, however, may adversely impact the integrity of the ACF bond and/or the electrical continuity of the metal traces within the flexible conductor.

According to various embodiments, a support element may be located proximate to the flexible conductor within one or more regions thereof prone to flexure. In example configurations, a portion of the flexible conductor may be disposed directly over the support element. In some embodiments, the support element may be integral with the supporting plate, and may include a metal such as aluminum. The support element may be configured to inhibit or prevent unintended/uncontrolled bending of the flexible conductor and thereby protect electrical connections within the display module.

### EXAMPLE EMBODIMENTS

### Example 1

A display module includes a display panel having a display active area including a plurality of display elements and a bezel region located outside of the display active area, a support plate underlying the display panel, a display driver integrated circuit (DDIC) disposed over a surface of the support plate opposite to the display panel, a flexible conductor attached to the display panel within the bezel region and electrically connecting the plurality of display elements with the display driver integrated circuit, and a support element located adjacent to the bezel region and directly contacting the flexible conductor.

### Example 2

The display module of Example 1, where the support element is configured to inhibit bending of the flexible conductor.

### Example 3

The display module of any of Examples 1 and 2, where the support element is configured to prevent failure of at least one of conductive traces within the flexible conductor and a bond between the flexible conductor and the display panel.

### Example 4

The display module of any of Examples 1-3, where the flexible conductor is bonded to the display panel using an electrically conductive adhesive bond.

### Example 5

The display module of Example 4, where the electrically conductive adhesive bond includes an anisotropic conductive film (ACF) bond.

### Example 6

The display module of any of Examples 1-5, where a top surface of the display panel within the bezel region is co-planar with a top surface of the support element.

### Example 7

The display module of any of Examples 1-6, where the support element and the support plate constitute a unitary part.

### Example 8

The display module of any of Examples 1-7, where the flexible conductor includes a first bending region adjacent to the support plate and a second bending region overlying the display panel within the bezel region.

### Example 9

The display module of Example 8, where the flexible conductor directly contacts the support element within the first bending region.

### Example 10

The display module of any of Examples 1-9, further including an anchoring element overlying a portion of the support element and a portion of the display panel within the bezel region, where a surface of the flexible conductor is bonded to both a lower surface of the anchoring element and an upper surface of the anchoring element.

### Example 11

The display module of any of Examples 1-10, further including a rigid support layer between the support plate and the display driver integrated circuit.

### Example 12

The display module of any of Examples 1-11, further including a layer of a thermally conductive adhesive between the display panel and the support plate.

### Example 13

A head-mounted display including the display module of any of Examples 1-12.

### Example 14

A display modules includes a display panel overlying and bonded to a support plate, the display panel including a plurality of display elements within an active area, a display driver integrated circuit disposed over the support plate opposite to the display panel, a flexible conductor electrically connecting the display driver integrated circuit with the plurality of display elements, and a support element directly underlying the flexible conductor adjacent to the display panel.

### Example 15

The display module of Example 14, where the support element is configured to inhibit bending of the flexible conductor.

### Example 16

The display module of any of Examples 14 and 15, where the flexible conductor is bonded to a surface of the display panel outside of the active area.

### Example 17

The display module of any of Examples 14-16, where the flexible conductor is bonded to the display panel using an electrically conductive adhesive bond.

### Example 18

The display module of any of Examples 14-17, where a surface of the display panel outside of the active area and a surface of the support element directly underlying the flexible conductor are co-planar.

### Example 19

The display module of any of Examples 14-18, where the support element and the support plate constitute a unitary part.

### Example 20

A display module includes a display panel overlying and bonded to a support plate, the display panel including a plurality of display elements within an active area, a display driver integrated circuit disposed over the support plate opposite to the display panel, a flexible conductor electrically connecting the display driver integrated circuit with the plurality of display elements, the flexible conductor having a first bending region and a second bending region, and a support element, where the flexible conductor directly overlies the support element within the first bending region and the flexible conductor directly overlies the support element within a planar region of the flexible conductor between the first bending region and the second bending region.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 700 in FIG. 7) or that visually immerses a user in an artificial reality (such as, e.g., virtual-reality system 800 in FIG. 8). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 7, augmented-reality system 700 may include an eyewear device 702 with a frame 710 configured to hold a left display device 715(A) and a right display device 715(B) in front of a user's eyes. Display devices 715(A) and 715(B) may act together or independently to present an image or series of images to a user. While augmented-reality system 700 includes two displays, embodiments of this disclosure may be implemented in augmented-reality systems with a single NED or more than two NEDs.

In some embodiments, augmented-reality system 700 may include one or more sensors, such as sensor 740. Sensor 740 may generate measurement signals in response to motion of augmented-reality system 700 and may be located on substantially any portion of frame 710. Sensor 740 may represent one or more of a variety of different sensing mechanisms, such as a position sensor, an inertial measurement unit (IMU), a depth camera assembly, a structured light emitter and/or detector, or any combination thereof. In some embodiments, augmented-reality system 700 may or may not include sensor 740 or may include more than one sensor. In embodiments in which sensor 740 includes an IMU, the IMU may generate calibration data based on measurement signals from sensor 740. Examples of sensor 740 may include, without limitation, accelerometers, gyroscopes, magnetometers, other suitable types of sensors that detect motion, sensors used for error correction of the IMU, or some combination thereof.

In some examples, augmented-reality system 700 may also include a microphone array with a plurality of acoustic transducers 720(A)-720(J), referred to collectively as acoustic transducers 720. Acoustic transducers 720 may represent transducers that detect air pressure variations induced by sound waves. Each acoustic transducer 720 may be configured to detect sound and convert the detected sound into an electronic format (e.g., an analog or digital format). The microphone array in FIG. 7 may include, for example, ten acoustic transducers: 720(A) and 720(B), which may be designed to be placed inside a corresponding ear of the user, acoustic transducers 720(C), 720(D), 720(E), 720(F), 720(G), and 720(H), which may be positioned at various locations on frame 710, and/or acoustic transducers 720(1) and 720(J), which may be positioned on a corresponding neckband 705.

In some embodiments, one or more of acoustic transducers 720(A)-(J) may be used as output transducers (e.g., speakers). For example, acoustic transducers 720(A) and/or 720(B) may be earbuds or any other suitable type of headphone or speaker.

The configuration of acoustic transducers 720 of the microphone array may vary. While augmented-reality system 700 is shown in FIG. 7 as having ten acoustic transducers 720, the number of acoustic transducers 720 may be greater or less than ten. In some embodiments, using higher numbers of acoustic transducers 720 may increase the amount of audio information collected and/or the sensitivity and accuracy of the audio information. In contrast, using a lower number of acoustic transducers 720 may decrease the computing power required by an associated controller 750 to process the collected audio information. In addition, the position of each acoustic transducer 720 of the microphone array may vary. For example, the position of an acoustic transducer 720 may include a defined position on the user, a defined coordinate on frame 710, an orientation associated with each acoustic transducer 720, or some combination thereof.

Acoustic transducers 720(A) and 720(B) may be positioned on different parts of the user's ear, such as behind the pinna, behind the tragus, and/or within the auricle or fossa. Or, there may be additional acoustic transducers 720 on or surrounding the ear in addition to acoustic transducers 720 inside the ear canal. Having an acoustic transducer 720 positioned next to an ear canal of a user may enable the microphone array to collect information on how sounds arrive at the ear canal. By positioning at least two of acoustic transducers 720 on either side of a user's head (e.g., as binaural microphones), augmented-reality device 700 may simulate binaural hearing and capture a 3D stereo sound field around about a user's head. In some embodiments, acoustic transducers 720(A) and 720(B) may be connected to augmented-reality system 700 via a wired connection 730, and in other embodiments acoustic transducers 720(A) and 720(B) may be connected to augmented-reality system 700 via a wireless connection (e.g., a BLUETOOTH connection). In still other embodiments, acoustic transducers 720(A) and 720(B) may not be used at all in conjunction with augmented-reality system 700.

Acoustic transducers 720 on frame 710 may be positioned in a variety of different ways, including along the length of the temples, across the bridge, above or below display devices 715(A) and 715(B), or some combination thereof. Acoustic transducers 720 may also be oriented such that the microphone array is able to detect sounds in a wide range of directions surrounding the user wearing the augmented-reality system 700. In some embodiments, an optimization process may be performed during manufacturing of augmented-reality system 700 to determine relative positioning of each acoustic transducer 720 in the microphone array.

In some examples, augmented-reality system 700 may include or be connected to an external device (e.g., a paired device), such as neckband 705. Neckband 705 generally represents any type or form of paired device. Thus, the following discussion of neckband 705 may also apply to various other paired devices, such as charging cases, smart watches, smart phones, wrist bands, other wearable devices, hand-held controllers, tablet computers, laptop computers, other external compute devices, etc.

As shown, neckband 705 may be coupled to eyewear device 702 via one or more connectors. The connectors may be wired or wireless and may include electrical and/or non-electrical (e.g., structural) components. In some cases, eyewear device 702 and neckband 705 may operate independently without any wired or wireless connection between them. While FIG. 7 illustrates the components of eyewear device 702 and neckband 705 in example locations on eyewear device 702 and neckband 705, the components may be located elsewhere and/or distributed differently on eyewear device 702 and/or neckband 705. In some embodiments, the components of eyewear device 702 and neckband 705 may be located on one or more additional peripheral devices paired with eyewear device 702, neckband 705, or some combination thereof.

Pairing external devices, such as neckband 705, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 700 may be provided by a paired device or shared between a paired device and an eyewear device, thus reducing the weight, heat profile, and form factor of the eyewear device overall while still retaining desired functionality. For example, neckband 705 may allow components that would otherwise be included on an eyewear device to be included in neckband 705 since users may tolerate a heavier weight load on their shoulders than they would tolerate on their heads. Neckband 705 may also have a larger surface area over which to diffuse and disperse heat to the ambient environment. Thus, neckband 705 may allow for greater battery and computation capacity than might otherwise have been possible on a stand-alone eyewear device. Since weight carried in neckband 705 may be less invasive to a user than weight carried in eyewear device 702, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 705 may be communicatively coupled with eyewear device 702 and/or to other devices. These other devices may provide certain functions (e.g., tracking, localizing, depth mapping, processing, storage, etc.) to augmented-reality system 700. In the embodiment of FIG. 7, neckband 705 may include two acoustic transducers (e.g., 720(I) and 720(J)) that are part of the microphone array (or potentially form their own microphone subarray). Neckband 705 may also include a controller 725 and a power source 735.

Acoustic transducers 720(I) and 720(J) of neckband 705 may be configured to detect sound and convert the detected sound into an electronic format (analog or digital). In the embodiment of FIG. 7, acoustic transducers 720(I) and 720(J) may be positioned on neckband 705, thereby increasing the distance between the neckband acoustic transducers 720(I) and 720(J) and other acoustic transducers 720 positioned on eyewear device 702. In some cases, increasing the distance between acoustic transducers 720 of the microphone array may improve the accuracy of beamforming performed via the microphone array. For example, if a sound is detected by acoustic transducers 720(C) and 720(D) and the distance between acoustic transducers 720(C) and 720(D) is greater than, e.g., the distance between acoustic transducers 720(D) and 720(E), the determined source location of the detected sound may be more accurate than if the sound had been detected by acoustic transducers 720(D) and 720(E).

Controller 725 of neckband 705 may process information generated by the sensors on neckband 705 and/or augmented-reality system 700. For example, controller 725 may process information from the microphone array that describes sounds detected by the microphone array. For each detected sound, controller 725 may perform a direction-of-arrival (DOA) estimation to estimate a direction from which the detected sound arrived at the microphone array. As the microphone array detects sounds, controller 725 may populate an audio data set with the information. In embodiments in which augmented-reality system 700 includes an inertial measurement unit, controller 725 may compute all inertial and spatial calculations from the IMU located on eyewear device 702. A connector may convey information between augmented-reality system 700 and neckband 705 and between augmented-reality system 700 and controller 725. The information may be in the form of optical data, electrical data, wireless data, or any other transmittable data form. Moving the processing of information generated by augmented-reality system 700 to neckband 705 may reduce weight and heat in eyewear device 702, making it more comfortable to the user.

Power source 735 in neckband 705 may provide power to eyewear device 702 and/or to neckband 705. Power source 735 may include, without limitation, lithium ion batteries, lithium-polymer batteries, primary lithium batteries, alkaline batteries, or any other form of power storage. In some cases, power source 735 may be a wired power source. Including power source 735 on neckband 705 instead of on eyewear device 702 may help better distribute the weight and heat generated by power source 735.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 800 in FIG. 8, that mostly or completely covers a user's field of view. Virtual-reality system 800 may include a front rigid body 802 and a band 804 shaped to fit around a user's head. Virtual-reality system 800 may also include output audio transducers 806(A) and 806(B). Furthermore, while not shown in FIG. 8, front rigid body 802 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 700 and/or virtual-reality system 800 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 700 and/or virtual-reality system 800 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 700 and/or virtual-reality system 800 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.”

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

Finally, for ease of use, the terms “including” and “having” (and their derivatives), as used in the specification and claims, are interchangeable with and have the same meaning as the word “comprising.” While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a support element that comprises or includes aluminum include embodiments where a support element consists essentially of aluminum and embodiments where a support element consists of aluminum.

What is claimed is:

1. A display module, comprising:
a display panel having a display active area including a plurality of display elements, and a bezel region located outside of the display active area;
a support plate underlying the display panel;
a display driver integrated circuit (DDIC) disposed over a surface of the support plate opposite to the display panel;
a flexible conductor bonded to the display panel within the bezel region and electrically connecting the plurality of display elements with the display driver integrated circuit; and
a support element located adjacent to the bezel region and directly contacting the flexible conductor.

2. The display module of claim 1, wherein the support element is configured to inhibit bending of the flexible conductor.

3. The display module of claim 1, wherein the support element is configured to prevent failure of at least one of conductive traces within the flexible conductor and a bond between the flexible conductor and the display panel.

4. The display module of claim 1, wherein the flexible conductor is bonded to the display panel using an electrically conductive adhesive bond.

5. The display module of claim 4, wherein the electrically conductive adhesive bond comprises an anisotropic conductive film (ACF) bond.

6. The display module of claim 1, wherein a top surface of the display panel within the bezel region is co-planar with a top surface of the support element.

7. The display module of claim 1, wherein the support element and the support plate comprise a unitary part.

8. The display module of claim 1, wherein the flexible conductor comprises a first bending region adjacent to the support plate and a second bending region overlying the display panel within the bezel region.

9. The display module of claim 8, wherein the flexible conductor directly contacts the support element within the first bending region.

10. The display module of claim 1, further comprising an anchoring element overlying a portion of the support element and a portion of the display panel within the bezel region, wherein a surface of the flexible conductor is bonded to both a lower surface of the anchoring element and an upper surface of the anchoring element.

11. The display module of claim 1, further comprising a rigid support layer between the support plate and the display driver integrated circuit.

12. The display module of claim 1, further comprising a layer of a thermally conductive adhesive between the display panel and the support plate.

13. A head-mounted display comprising the display module of claim 1.

14. A display module, comprising:
a display panel overlying and bonded to a support plate, the display panel including a plurality of display elements within an active area;
a display driver integrated circuit disposed over the support plate opposite to the display panel;
a flexible conductor electrically connecting the display driver integrated circuit with the plurality of display elements; and
a support element directly underlying the flexible conductor adjacent to the display panel.

15. The display module of claim 14, wherein the support element is configured to inhibit bending of the flexible conductor.

16. The display module of claim 14, wherein the flexible conductor is bonded to a surface of the display panel outside of the active area.

17. The display module of claim 14, wherein the flexible conductor is bonded to the display panel using an electrically conductive adhesive bond.

18. The display module of claim 14, wherein a surface of the display panel outside of the active area and a surface of the support element directly underlying the flexible conductor are co-planar.

19. The display module of claim 14, wherein the support element and the support plate comprise a unitary part.

20. A display module, comprising:
a display panel overlying and bonded to a support plate, the display panel including a plurality of display elements within an active area;
a display driver integrated circuit disposed over the support plate opposite to the display panel;
a flexible conductor electrically connecting the display driver integrated circuit with the plurality of display elements, the flexible conductor having a first bending region and a second bending region; and
a support element, wherein the flexible conductor directly overlies the support element within the first bending region and the flexible conductor directly overlies the support element within a planar region of the flexible conductor between the first bending region and the second bending region.
